(19) United States
(12) Patent Application Publication
(10) Pub. No.: US 2007/0144889 A1
(43) Pub. Date: Jun. 28, 2007

(54) Machine for treating substrates and method

(76) Inventors: Erkan Koparal, Nidderau (DE); Dieter Haas, Bruchkobel (DE)

Correspondence Address: VAN DYKE, GARDNER, LINN AND BURKHART, LLP, 2851 CHARLEVOIX DRIVE, S.E., P.O. BOX 888695, GRAND RAPIDS, MI, 49588-8695, US

(21) Appl. No.: 11/580,721

(22) Filed: Oct. 13, 2006

(30) Foreign Application Priority Data
Dec. 22, 2005 (DE) 10 2005061563.5

(51) Int. Cl. C23C 14/32; C23C 14/00; C23C 16/00

(52) U.S. Cl. 204/192.1; 118/719; 204/298.25

(57) ABSTRACT

A machine 1 for treating substrates S comprises an infeed area 6, at least a first process chamber 2, a second process chamber 3, a third process chamber 4, and a fourth process chamber 8 for the execution of a treatment, for example the application of a coating to a substrate S for coating, as well as an outfeed area 7. The four process chambers 2,3, 4 and 8 are connected to a central transport chamber 5. The first process chamber 2 fourth process chamber 8 are each arranged between one of the lock areas 6 or 7 and the central transport chamber 5 in series. The second process chamber 3 and the third process chamber 4 are connected in parallel and independently accessible from each other to the central transport chamber. The treatment method comprises the stages: a) infeed of a substrate into the machine 1; b) transport of the substrate S into the first process chamber 2 and execution of a first treatment stage; c) transport of the substrate S into the central transport chamber 5; d) transport of the substrate S alternatively into the second process chamber 3 or the third process chamber 4, and execution of a second treatment stage; e) transport of the substrate S into the central transport chamber 5; and g) outfeed of the substrate S from the machine 1.

The invention concerns a machine for treating substrates, comprising at least a first process chamber, a second process chamber and a third process chamber for treating the substrates, a central transport chamber to which the at least three process chambers are attached, and a first lock area for infeed or outfeed of the substrates into the machine or out of the machine. Further, the invention concerns a method for treating substrates, especially for execution in the above-mentioned machine.

In a series of applications, substrates are subjected to several treatment stages, for example coatings. One of many examples of multiple coating of substrates is TFT metallization (thin film transistor) in which two to three different metals are applied by sputtering. In layer systems having several layers, it may be necessary to adjust the layer thickness of the individual layers such that they are different. The coating time in a certain coating stage also changes with the layer thickness, however.

For example, it may be necessary during the TFT metallization to form the second layer much thicker than the underlying first layer and the overlying third layer.

Different machine configurations have been proposed for the production of such layer systems having several layers.

For example, EP 0 277 536 A1 describes a typical inline arrangement, i.e. a series arrangement of different coating chambers. The substrates are transported from one process chamber into the next by means of a transport system.

An alternative to this is offered by so-called cluster arrangements, such as is revealed in U.S. Pat. No. 5,102,495. In such arrangements, the process chambers in which similar or different processes may occur are optionally accessible from the central transport chamber. The introduction of substrates into the process chambers and the removal of substrates from the process chambers generally proceeds in accordance with a predefined temporal workflow scheme. In this machine type, too, the layers of a multi-layer system are deposited sequentially one after the other on the substrate.

In the case of inline machine configurations, the thickest layer determines the cycle time of the entire system, given a roughly constant rate and sequential coating. As a result, just a single “long” coating time for one of the layers leads to long cycle times overall, e.g. of 90 to 120 seconds for conventional TFT metallization. Coating chambers with shorter coating times are not fully utilized, however, and a “backlog” builds up in front of the chamber with the longest coating time.

To be sure, several processes—similar or different—may be performed in conventional cluster machines. However, the choice of time window for processes of different length is restricted on one hand by the utilization of the transport and distribution system for distributing the substrates to the process chambers. If, for example, the substrates are distributed to the chambers by a rotary module, “rotation on the rotary module” also constitutes a process stage that requires time. Especially, overlapping may occur during loading of the rotary module with regard to optimum temporal workflow. Additionally, overlapping may occur during chamber loading.

Overall, it may be said that a cluster arrangement may lead to waiting times during loading of the distribution system, a fact which negatively impacts the cycle times.

Starting from this, the object of the present invention is to provide a machine for treating substrates and a method for treating substrates with whose aid the cycle time for producing multi-layer systems may be reduced overall.

This object is achieved in this invention by a machine for treating substrates in accordance with claim 1 and a method for treating substrates in accordance with claim 10.

The machine in accordance with the invention for treating substrates comprises at least a first process chamber, a second process chamber and a third process chamber for treating a substrate. At least these three process chambers are connected to a central transport chamber. Further, a first lock area for infeed or outfeed of the substrates into the machine or out of the machine is provided. The first process chamber is arranged between the first lock area and the central transport chamber in series with the first lock area and the central transport chamber. The second process chamber and the third process chamber are accessible independently of each other, i.e. connected in parallel to the central transport chamber. The three mentioned process chambers are in principle arranged around the central transport chamber. Several or preferably all adjacent chambers can be closed off from each other by valve doors or flaps.

By the arrangement of the invention, a combination of a parallel and a serial arrangement is realized. The serial arrangement of the first lock area, the first process chamber and the central transport chamber means that the substrate coming from one side of the lock area is transported via a first opening into the first process chamber. After the first coating stage, for example the application of the first layer to the substrate, the substrate is transported from the first process chamber via a second opening into the central transport chamber. As a result, during operation of the machine, one substrate after another is transported in the same direction through the first process chamber. Each of the substrates receives a first treatment in the first process chamber, for example a first coating.

The invention comprises all arrangements from a combination of inline and cluster arrangements. This means that the chambers in the claimed configurations may be connected to each other directly, for example by valves. However, for example, further treatment chambers could be arranged between the lock area and the first treatment chamber, depending on which treatment is to be performed, for example which layer system is to be produced.

In accordance with the invention, the second and the third process chambers are connected “in parallel” to the central transport chamber. “In parallel” here does not necessarily mean a parallel alignment of the process chambers in the geometrical sense. Rather, a parallel arrangement means that the two process chambers are each connected to the central transport chamber and are each accessible in parallel and selectively from the central transport chamber via an opening. The second and the third chamber are therefore not arranged in series with each other.

A substrate transported from the first process chamber into the central transport chamber can therefore be optionally processed further in the second or the third process chamber. While the first process chamber is passed through by each of the substrates transported through the machine, the second and the third process chamber can be loaded, for example in alternating fashion, during operation with substrates from the first process chamber via the central transport chamber. It goes without saying that the number of process chambers attached in parallel to the central transport chamber need not be restricted to two. The number depends primarily on the treatment time required for the individual treatment stages.

It should be mentioned at this point that the invention is intended to be directed essentially at the configuration of the individual process chambers. In the primary application case, the process chambers are intended to be coating chambers, especially sputtering chambers, for applying several metal layers to a substrate by means of sputtering. In another embodiment, however, the process chambers may also be provided for alternative processes of surface treatment, for example etching, or for other processes for layer formation, for example CVD coating.

In comparison with conventional cluster machines, the advantage derived is that of an optimal time workflow of the overall process, including transport system and rotary module loading. Temporal overlapping of chamber loading is avoided, with a result that no waiting times occur.

Especially, the machine comprises transport means for transporting the substrates through the machine from the first lock area into the first process chamber for the execution of a first treatment stage, for example for applying a first layer to the substrate, for transport from the first process chamber into the central transport chamber, for transport from the central transport chamber optionally into the second or the third process chamber for execution of a second treatment stage, for example for applying a second layer to the substrate, and for return transport from the second or the third process chamber into the central transport chamber. In this central transport chamber, each substrate is transported either into the second or into the third process chamber For this, the transport means may have a rotary platform in the central transport chamber that can be aligned by rotation about a vertical axis for the purpose of loading the second or the third process chamber or for receiving a substrate from the second or the third process chamber. Especially advantageous is a machine in which the substrates are essentially vertically arranged during transport through the machine and while they are being processed. An essentially vertical alignment is also intended to include an alignment of the substrates with an angle of up to 5° or up to 10° to the right angle.

The central transport chamber preferably has a rotary platform for aligning the substrates optionally towards the opening of the second process chamber or towards the opening of the third process chamber for transporting the substrates optionally into the second or third process chamber and for receiving the substrates from the second or the third process chamber. As a result, sequential introduction of the substrates, for example in alternation into the second and the third process chamber, is possible. In the machine configuration of the invention, the substrates can be processed in the second and the third process chamber at overlapping times.

Especially, the machine has a second lock area for outfeed of the substrates from the machine. The second lock area may be connected either directly or indirectly, i.e. with further chambers connected in between, to the central transport chamber.

In a special embodiment, the machine comprises a fourth process chamber, which is connected to the central transport chamber, with the fourth process chamber arranged in series between the central transport chamber and the second lock area. By means of the fourth process chamber, the machine of the invention is therefore extended by a further inline component. In this extended machine configuration, a substrate passes through the first treatment chamber for execution of a first treatment stage, for example application of a first layer to the substrate, the second or third treatment chamber for execution of a second treatment stage, for example application of a second (generally thicker) layer, and then the fourth treatment chamber for execution of a third treatment stage, for example application of a third layer (which is generally thinner than the second layer). The fourth process chamber can be connected directly or indirectly to the second lock area and/or the central transport chamber. An important fact is that the three chambers (central transport chamber, fourth process chamber and lock chamber) are connected to each other in series, i.e. that all substrates to be processed pass through the fourth process chamber in the same direction.

Adjacent chambers, especially all adjacent chambers, can be closed off from each other by valve doors. By virtue of the fact that all adjacent chambers can be sealed off vacuum tight from each other by valves, different processes, such as PECVD or etching, can be performed in the process chambers, without the requisite process gases negatively influencing the adjacent sputtering processes for the duration of the process.

In a second special embodiment, the first process chamber for executing a first treatment stage, for example a first coating process, is set up and the second and the third process chamber are set up for the execution of a second treatment stage, for example for the execution of a second coating process. Generally, each substrate will pass through a first shorter process and a second longer lasting process, for example each substrate will receive a thinner first layer and a thicker second layer. The thicker second layer is received by each substrate alternatively in the second or the third process chamber. The machine configuration of the invention is therefore especially advantageous when the second process lasts longer than the first. Through the alternative choice of the second or third treatment chamber for the second process, at least two substrates can be treated in overlapping time. In this way, the entire cycle time is reduced.

The process times for the processes executed in the first and fourth process chambers are preferably shorter than the process times for the processes executed in the second and third process chambers. Especially, the intention is that the process times in the first and fourth chamber do not deviate too much from each other, since they proceed “in line.”

In a special embodiment, the machine is formed for the formation of TFT (thin film transistor) metallization, with one of the layers in the layer sequence being alternatively applied in the second process chamber or in the third process chamber.

In a special embodiment, the first lock area and/or the second lock area each comprises a lock chamber and a transfer chamber.

The object of the invention is solved by a method for treating substrates, especially for executing the method in a machine as described above, comprising the stages: a) infeed of a substrate into the machine; b) transport of the substrate into the first process chamber and execution of a first treatment stage (for example application of a first layer to the substrate); c) transporting of the substrate into the central transport chamber; d) transporting of the substrate alternatively into the second or the third process chamber; and execution of a second treatment stage (for example application of a second layer to the substrate); e) return transport of the substrate into the central transport chamber; and g) outfeed of the substrate from the machine.

The basic idea of the invention also becomes clear from the stages of the method. First, the substrate is transported “in line” from an infeed area into a first process chamber and from there further into a central transport chamber. Through the provision of a second and third process or coating chamber, which are connected “in parallel” to the central transport chamber, an alternative option is created of executing the further treatment stage, for example the application of a further layer, alternatively in the second or third process chamber. This means that the second treatment stage in the second and third process chamber can be partly executed in overlapping time. In other words, in coating processes, the further layer may be applied to at least two substrates in the second and third process chamber in partly overlapping time.

As part of the invention, it is also intended to be possible to arrange the first process chamber in series with the central transport chamber and outfeed area—instead of in series with an infeed area and the central process chamber. In this case, method stage b) “transport of the substrate into the first process chamber and execution of a second treatment stage (for example, application of a layer to the substrate) would be incorporated between method stages e) and f). The layer applied in stage d) would naturally then also lie beneath the layer applied in stage b).

Preferably, the method of the invention may be extended by a further method stage f), which occurs after stage e) and prior to stage g). This stage contains transporting of the substrate into the fourth process chamber and the execution of a third treatment stage (for example, application of a third coating to the substrate). This extended method is especially advantageous when a layer system is to be produced from at least a first and third thin layer and a second thicker layer between them. Since, in this case, the cycle time for the position of the thicker layer is longer (for example, twice as long as for the thinner layers), the cycle time in inline or pure cluster machines in which the layers are deposited sequentially is determined by the second coating stage. With the present method, the cycle time can be reduced overall by the fact that the thicker layer can be applied at least partly in overlapping time to two substrates transported in succession into the machine. This means that sequential (for the first and third layer) and parallel coating (for the second) are realized in one machine. The same applies for other treatment stages of different duration.

For the first and third treatment or the first and third layer, the machine is configured as an inline machine. For each of these treatments or layers, the treatment time corresponds to the cycle time minus the travel time. For the second treatment, two parallel treatment or coating stations (i.e. two treatment or coating stations accessible in parallel from the central transport chamber) are provided. These are loaded in alternation in every second cycle with the substrate transported from the first process chamber into the central transport chamber. This means that the treatment time for the execution of the second treatment stage or for the application of the second layer corresponds roughly to twice the cycle time minus the travel time.

In a special embodiment, infeed of the substrate into the machine occurs via an infeed chamber and a transfer chamber.

Especially, the same process may occur in the second and third process chamber. This process will in each case generally last longer than the processes occurring in the first and, as necessary, the fourth process chamber.

The treatment times of the processes occurring in the first and fourth process chamber should be shorter than those in the second and third chamber. Furthermore, the treatment times in the first and fourth chamber should be adjusted to each other.

Especially, at least three layers for the purposes of TFT metallization are applied by the process of the invention.

During transport through the machine, the substrates are aligned preferably essentially vertically, i.e. at right angles to, or at a relatively small angle of up to 5° or 10° to the right angle. This affords a space-saving way of also coating larger substrates.

Especially, the method of the invention is sequentially staggered temporally with at least a second substrate S repeated. In this regard, certain method stages, especially the second metallization (e.g. Al), are executed in overlapping time on both substrates.

This means that the following process can occur in the machine, as illustrated by two substrates:
Juncture 1: Substrate 1: Method stage a);
Juncture 2: Substrate 1: Method stage b), Substrate 2: Method stage a);
Juncture 3: Substrate 1: Method stage c), Substrate 2: Method stage b),
Juncture 4: Substrate 1: Method stage d) in the second process chamber, Substrate 2: Method stage c),
Juncture 5: Substrate 1: Continuation of method stage d) in the second process chamber, Substrate 2: Method stage d) in the third process chamber;
Juncture 6: Substrate 1: Method stage e), Substrate 2: Continuation of method stage d) in the third process chamber;
Juncture 7: Substrate 1: Method stage f), Substrate 2: Method stage e);
Juncture 8: Substrate 1: Method stage g), Substrate 2: Method stage f),
Juncture 9: Substrate 1: outfed Substrate 2: Method stage g),

Naturally, the second substrate may be followed sequentially by further substrates. From this example, it is clear that the cycle time can be reduced with the method of the invention. Especially, in method stage 5, temporal overlapping processing of the substrates occurs during application of the second layer.

Further objects and advantages of the invention result from the specific description of specific embodiments. In these,

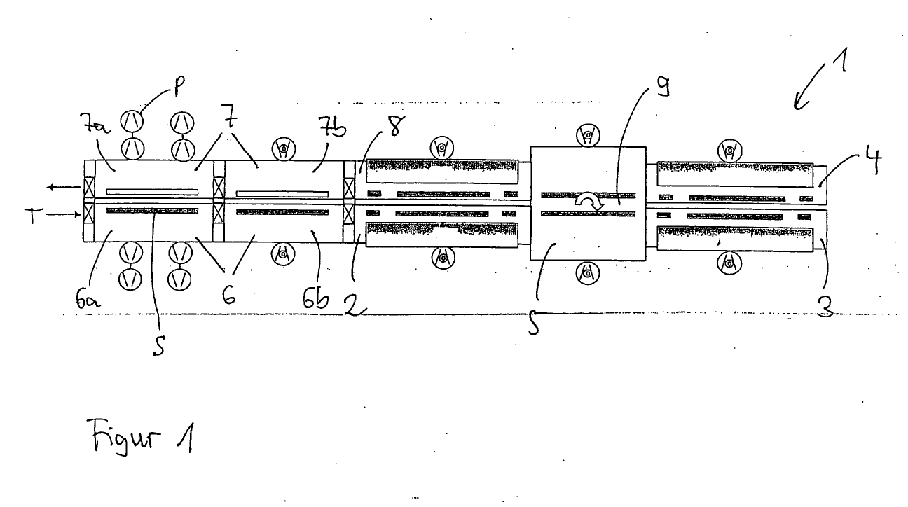

FIG. 1 is a treatment machine in accordance with the invention; and

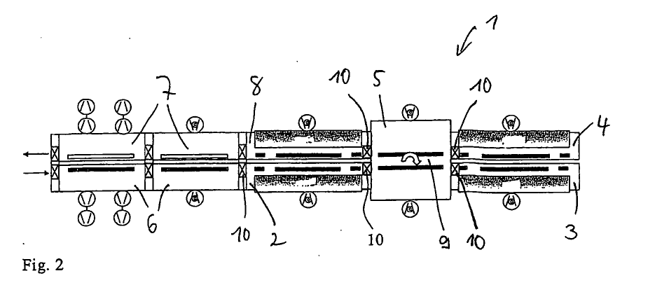

FIG. 2 an alternative embodiment of the machine of the invention.

FIG. 1 shows a machine 1 for coating of substrates S. Machine 1 comprises standard components, such as a pump system, indicated by the letter P to designate a pump symbol.

The illustrated coating machine 1 has an arrangement of chambers or stations 2, 3, 4, 5, 6, 7 and 8. Overall, coating stations 2, 3, 4 and 8 are provided. Additionally, the machine comprises an infeed area 6 and an outfeed area 7 as well as a central transport chamber 5.

The first coating chamber 2 is arranged between the infeed station 6 and the central transport chamber 5 and in series (“in line”) with these chambers. The fourth coating chamber 8 is arranged between the central transport chamber 5 and the outfeed station in series (“in line”) with these. In the first and fourth coating chamber 2, 8, preferably metallization, for example with Ti (titanium) or Mo (molybdenum), is executed. In this regard, the same or different material with predefined layer thicknesses may be applied in the two chambers 2 and 8.

In contrast, the coating chambers 3 and 4 are arranged in parallel. This means that a substrate S does not pass through chambers 3 or 4 in one direction, but, as in a cluster machine, the substrates S are transported from the central transport chamber 5 alternatively and optionally into one of the coating chambers 3 and 4, processed there, and then transported back into the central transport chamber 5. Preferably, in the second or third coating chamber, further metallization is applied onto the first metallization, for example (but not restricted to) Al (aluminum).

The machine 1 illustrated is thus a combined inline-cluster configuration with the aid of which the cycle time for sequential processing of several substrates may be reduced.

Especially, machine 1 is designed for TFT metallization.

The substrates S are first introduced into the machine 1 via infeed station 6. The infeed station 6 in the current case consists of an infeed chamber 6a and a transfer chamber 6b.

In the first coating chamber 2, the substrates S are coated with a first layer by means of sputtering. The substrates S coated with the first layer and introduced in succession into machine 1 are provided, in the second or third coating chamber 3 or 4 alternatively and in alternation, with a second layer (e.g. Al) by means of sputtering. In the fourth coating station 8, a further layer is applied to the second layer by means of sputtering. The substrates S in turn pass through the last mentioned method stage successively and separated in time. The process times of the treatment stages occurring in coating stations 2 and 8 should be coordinated with each other and selected so as to be roughly of the same length.

Outfeed from the machine 1 proceeds via outfeed station 7, which is connected to the fourth coating chamber 8. The outfeed station 7 comprises in the current case an outfeed chamber 7a and a transfer chamber 7b arranged between the outfeed chamber 7a and the fourth coating chamber 8.

The central transport chamber 5 essentially serves the purpose of successively receiving substrates S from the first coating chamber 2 and then further transporting these in alternation into the second coating chamber 3 or, alternatively, into the third coating chamber 4. To this end, the substrates S are received on a rotary platform 9 and aligned by the rotary platform 9 in the central transport chamber 5 relative to the opening of the second chamber 3 or of the third chamber 4.

The second coating chamber 3 and the third coating chamber 4 are both connected directly to the central transport chamber 5 and thus facilitate parallel or optional access to the two chambers 3 and 4.

From platform 9, substrate S is transported into the second or third chamber 3 or 4. After processing in the second or third chamber 3 or 4, the treated substrate S is again received on platform 9. The substrate S is aligned by means of platform 9 with the opening of the fourth coating chamber 8, such that transport into the fourth coating chamber 8 with subsequent third coating may occur.

Since the second layer is much thicker than the first and the third layers, the process is much longer by comparison. However, in order that the overall cycle time, which is determined in conventional “in-line” machines by the slowest process stage, may be reduced, the two parallel coating stations 3 and 4 are provided in which sequential successions of substrates S are subjected at least partially in overlapping time to the same process. In comparison with conventional cluster machines, the advantage derived is that of optimum temporal workflow of the overall process, including transport system and rotary module loading. Overlapping of chamber loading is avoided, with a result that no waiting times occur.

An alternative embodiment is shown in FIG. 2. The machine essentially corresponds to the machine shown in FIG. 1, with the same components being marked with the same labels. Additionally, all adjacent chambers in this embodiment, i.e. especially also chambers 2 and 5, 5 and 3,5 and 4, 5 and 8, may be closed off vacuum tight from each other by valve doors 10. As a result, different processes, such as PECVD or etching may be performed in one machine in process chambers 2, 3, 4, and 8. The valves prevent the process gases required for the various processes from gaining access into adjacent chambers where they would negatively affect the processes of occurring there.

The temporal sequence of the process within the coating machine 1 is clear from the following table 1, where the number of the substrate S corresponds to the order of infeed, tx represents a certain time sequence, and the numbers in the table represent the location (corresponding to the labels of the figure) of a certain substrate S at a certain juncture tx. “5-in” means, for example, that transport into chamber 5 proceeds in time sequence tx.

TABLE 1

| | Substrate No. | | |
|---|---|---|---|
| t | 1 | 2 | 3 |
| t1 | 6a-in | | |
| t2 | 6a | | |
| t3 | 6b-in | | |
| t4 | 6b | | |
| t5 | 6b | 6a-in | |
| t6 | 2-in | 6a | |
| t7 | 2 | 6b-in | |
| t8 | 2 | 6b | |
| t9 | 5-in, 3-in | 6b | 6a-in |
| t10 | 3 | 2-in | 6a |
| t11 | 3 | 2 | 6b-in |
| t12 | 3 | 2 | 6b |
| t13 | 3 | 5-in | 6b |
| t14 | 3 | Rotation of the | 2-in |
| | | platform, 4-in | |
| t15 | 5-in | 4 | 2 |
| t16 | Rotation of the platform, | 4 | 2 |
| | 8-in | | |
| t17 | 8 | 4 | 5-in, 3-in |
| t18 | 8 | 4 | 3 |
| t19 | 7b-in | 4 | 3 |
| t20 | 7b | 5-in, 8-in | 3 |
| t21 | 7b | 8 | 3 |
| t22 | 7a-in | 8 | 3 |
| t23 | OUT | 7b-in | 5-in |
| t24 | | 7b | Rotation of the platform, |
| | | | 8-in |
| t25 | | 7b | 8 |
| t26 | | 7a-in | 8 |
| t27 | | OUT | 7b-in |
| t28 | | | 7b |
| t29 | | | 7b |
| t30 | | | 7a-in |
| t31 | | | OUT |

To further illustrate the method of the invention, the following Tables 2 and 3 compare method cycles for the treatment of four substrates a) in a conventional cluster machine (Table 2), and b) in the combined inline-cluster machine of the invention (Table 3).

A coating cycle consists in each case of infeed, coating with a first layer in a first chamber, coating with a second layer in a second or a third chamber, and coating with a third layer in a fourth chamber. In this regard, method stage “Coating 1” requires three time units, method stage “Coating 2” six time units, and, in turn, method stage “Coating 3” three time units. The use of the rotary module in the central distribution station (central transfer chamber) requires one time unit. Each substrate passes through the coating stations 1, alternatively 2 or 3, and 4 in that order. The term “rotary module” means that a substrate is transported either via the rotary module or is advanced to the rotary module and, through rotation, brought into an alternative position and then transported into the target chamber.

Table 2 refers to a conventional cluster arrangement with the coating stations 1 to 4, which are arranged around a central transfer chamber (with a rotary module). Equally, the infeed and the outfeed station are connected to the central transfer chamber.

As is evident from Table 2, a total of 35 time units is required for processing the four substrates. On account of the occupancy of certain chambers or of the rotary module at certain junctures, time delays may occur during the processing flow. For example, substrate 4 can be further processed at timing sequences 17 and 18 because first chamber 1 and then, in the next time sequence, the rotary module is occupied. The substrate therefore has to “wait” until the next station is free. The accumulation of individual delays produces an overall delay which determines the overall cycle time for the processing of the four substrates.

Table 3 also shows the coating of four substrates with the same layer sequence, i.e. with the same coating times and pass-through times through the individual machine components in a combined inline-cluster arrangement of the invention, as illustrated in the figure.

It can be seen that, given the same process times for processing of the four substrates, only 32 timing sequences are required. This is primarily due to the fact that the combination of the arrangement of the chambers in series and parallel means that the rotary module is required less often. Also, loading of the chambers with substrates which delay processing of subsequent substrates can be more easily avoided in the process sequence illustrated. Moreover, time can also be saved by the fact that the rotary module actually only has to rotate for every second substrate arriving. Otherwise, the substrate passes directly across the rotary module from one starting chamber into the target chamber. Above and beyond that, linear transport of the substrate S from the lock chamber into the first process chamber or from the fourth process chamber into the lock chamber for outfeed requires much less time than for transport to the rotary module, rotation or alignment of the module and subsequent transport into the respective process chamber.

Overall, a time saving of three timing sequences is achieved for the process described in the example. Just how great the time saving for different processes actually is depends critically on the duration of the individual processing and transport stages.

TABLE 2
Cluster machine:

| | Substrate 1: | Substrate 2: | Substrate 3: | Substrate 4: |
|---|---|---|---|---|
| Time sequence 1 | Infeed | | | |
| Time sequence 2 | Infeed | | | |
| Time sequence 3 | Infeed | | | |
| Time sequence 4 | Rotary module | Infeed | | |
| Time sequence 5 | Coating 1 in chamber 1 | Infeed | | |
| Time sequence 6 | Coating 1 in chamber 1 | Infeed | | |
| Time sequence 7 | Coating 1 in chamber 1 | [Chamber 1 occupied → | [Lock occupied] | |
| | | wait in lock] | | |
| Time sequence 8 | Rotary module | [Rotary module occupied] | [Lock occupied] | |
| | | wait in lock] | | |
| Time sequence 9 | Coating 2 in chamber 2 | Rotary module | Infeed | |
| Time sequence | Coating 2 in chamber 2 | Coating 1 in chamber 1 | Infeed | |
| 10 | | | | |
| Time sequence | Coating 2 in chamber 2 | Coating 1 in chamber 1 | Infeed | |
| 11 | | | | |
| Time sequence | Coating 2 in chamber 2 | Coating 1 in chamber 1 | [Chamber 1 occupied → | [Lock occupied] |
| 12 | | | wait in lock] | |
| Time sequence | Coating 2 in chamber 2 | Rotary module | [Rotary module occupied →] | [Lock occupied] |
| 13 | | | wait in lock] | |
| Time sequence | Coating 2 in chamber 2 | Coating 2 in chamber 3 | Rotary module | Infeed |
| 14 | | | | |
| Time sequence | Rotary module | Coating 2 in chamber 3 | Coating 1 in chamber 1 | Infeed |
| 15 | | | | |
| Time sequence | Coating 3 in chamber 4 | Coating 2 in chamber 3 | Coating 1 in chamber 1 | Infeed |
| 16 | | | | |
| Time sequence | Coating 3 in chamber 4 | Coating 2 in chamber 3 | Coating 1 in chamber 1 | [Chamber 1 occupied → |
| 17 | | | | wait in lock] |
| Time sequence | Coating 3 in chamber 4 | Coating 2 in chamber 3 | Rotary module | [Rotary module occupied →] |
| 18 | | | | wait in lock] |
| Time sequence | Rotary module | Coating 2 in chamber 3 | Coating 2 in chamber 2 | Rotary module |
| 19 | | | | |
| Time sequence | Outfeed | Rotary module | Coating 2 in chamber 2 | Coating 1 in chamber 1 |
| 20 | | | | |
| Time sequence | | Coating 3 in chamber 4 | Coating 2 in chamber 2 | Coating 1 in chamber 1 |
| 21 | | | | |
| Time sequence | | Coating 3 in chamber 4 | Coating 2 in chamber 2 | Coating 1 in chamber 1 |
| 22 | | | | |
| Time sequence | | Coating 3 in chamber 4 | Coating 2 in chamber 2 | Rotary module |
| 23 | | | | |
| Time sequence | | Rotary module | Coating 2 in chamber 2 | Coating 2 in chamber 3 |
| 24 | | | | |
| Time sequence | | Outfeed | Rotary module | Coating 2 in chamber 3 |
| 25 | | | | |
| Time sequence | | | Coating 3 in chamber 4 | Coating 2 in chamber 3 |
| 26 | | | | |
| Time sequence | | | Coating 3 in chamber 4 | Coating 2 in chamber 3 |
| 27 | | | | |
| Time sequence | | | Coating 3 in chamber 4 | Coating 2 in chamber 3 |
| 28 | | | | |
| Time sequence | | | Rotary module | Coating 2 in chamber 3 |
| 29 | | | | |
| Time sequence | | | Outfeed | Rotary module |
| 30 | | | | |
| Time sequence | | | | Coating 3 in chamber 4 |
| 31 | | | | |
| Time sequence | | | | Coating 3 in chamber 4 |
| 32 | | | | |
| Time sequence | | | | Coating 3 in chamber 4 |
| 33 | | | | |
| Time sequence | | | | Rotary module |
| 34 | | | | |
| Time sequence | | | | Outfeed |
| 35 | | | | |

TABLE 3
Combined inline-cluster machine:

| | Substrate 1: | Substrate 2: | Substrate 3: | Substrate 4: |
|---|---|---|---|---|
| Time sequence 1 | Infeed | | | |
| Time sequence 2 | Infeed | | | |
| Time sequence 3 | Infeed | | | |
| Time sequence 4 | Transport into chamber 1 | | | |
| Time sequence 5 | Coating 1 in chamber 1 | Infeed | | |
| Time sequence 6 | Coating 1 in chamber 1 | Infeed | | |
| Time sequence 7 | Coating 1 in chamber 1 | Infeed | | |
| Time sequence 8 | Rotary module | Transport into chamber 1 | | |
| Time sequence 9 | Coating 2 in chamber 2 | Coating 1 in chamber 1 | Infeed | |
| Time sequence | Coating 2 in chamber 2 | Coating 1 in chamber 1 | Infeed | |
| 10 | | | | |
| Time sequence | Coating 2 in chamber 2 | Coating 1 in chamber 1 | Infeed | |
| 11 | | | | |
| Time sequence | Coating 2 in chamber 2 | Rotary module | Transport into chamber 1 | |
| 12 | | | | |
| Time sequence | Coating 2 in chamber 2 | Coating 2 in chamber 3 | Coating 1 in chamber 1 | Infeed |
| 13 | | | | |
| Time sequence | Coating 2 in chamber 2 | Coating 2 in chamber 3 | Coating 1 in chamber 1 | infeed |
| 14 | | | | |
| Time sequence | Rotary module | Coating 2 in chamber 3 | Coating 1 in chamber 1 | Infeed |
| 15 | | | | |
| Time sequence | Coating 3 in chamber 4 | Coating 2 in chamber 3 | Rotary module | Transport into chamber 1 |
| 16 | | | | |
| Time sequence | Coating 3 in chamber 4 | Coating 2 in chamber 3 | Coating 2 in chamber 2 | Coating 1 in chamber 1 |
| 17 | | | | |
| Time sequence | Coating 3 in chamber 4 | Coating 2 in chamber 3 | Coating 2 in chamber 2 | Coating 1 in chamber 1 |
| 18 | | | | |
| Time sequence | Transport into outlet lock | Rotary module | Coating 2 in chamber 2 | Coating 1 in chamber 1 |
| 19 | | | | |
| Time sequence | Outfeed | Coating 3 in chamber 4 | Coating 2 in chamber 2 | Rotary module |
| 20 | | | | |
| Time sequence | | Coating 3 in chamber 4 | Coating 2 in chamber 2 | Coating 2 in chamber 3 |
| 21 | | | | |
| Time sequence | | Coating 3 in chamber 4 | Coating 2 in chamber 2 | Coating 2 in chamber 3 |
| 22 | | | | |
| Time sequence | | Transport into outlet lock | Rotary module | Coating 2 in chamber 3 |
| 23 | | | | |
| Time sequence | | Outfeed | Coating 3 in chamber 4 | Coating 2 in chamber 3 |
| 24 | | | | |
| Time sequence | | | Coating 3 in chamber 4 | Coating 2 in chamber 3 |
| 25 | | | | |
| Time sequence | | | Coating 3 in chamber 4 | Coating 2 in chamber 3 |
| 26 | | | | |
| Time sequence | | | Transport into outlet lock | Rotary module |
| 27 | | | | |
| Time sequence | | | Outfeed | Coating 3 in chamber 4 |
| 28 | | | | |
| Time sequence | | | | Coating 3 in chamber 4 |
| 29 | | | | |
| Time sequence | | | | Coating 3 in chamber 4 |
| 30 | | | | |
| Time sequence | | | | Transport into outlet lock |
| 31 | | | | |
| Time sequence | | | | Outfeed |
| 32 | | | | |
| Time sequence | | | | |
| 33 | | | | |
| Time sequence | | | | |
| 34 | | | | |
| Time sequence | | | | |
| 35 | | | | |

1-16. (canceled)

17. A machine for treating substrates, said machine comprising:
at least a first process chamber, a second process chamber and a third process chamber for executing a first treatment stage;
a central transport chamber to which at least the first, second, and third process chambers are connected;
a first lock area for infeed or outfeed of the substrates into the machine or out of the machine; and
wherein the first process chamber is arranged between the first lock area and the central transport chamber in series with the first lock area and the central transport chamber, and the second process chamber and the third process chamber being connected to the central transport chamber and accessible independently from each other.

18. A machine in accordance with claim 17, further comprising transport means for transporting the substrates through the machine from the first lock area into the first process chamber for the execution of a first treatment stage, for transport from the first process chamber into the central transport chamber, for transport from the central transport chamber optionally into the second process chamber or into the third process chamber for the execution of a second treatment stage, and for return transport from the second process chamber or from the third process chamber into the central transport chamber.

19. A machine in accordance with claim 17, wherein the central transport chamber has a rotary platform for aligning the substrates optionally towards the opening of the second process chamber or towards the opening of the third process chamber and for receiving the substrates from the second process chamber or from the third process chamber.

20. A machine in accordance with claim 17 further comprising a second lock area for outfeeding the substrates from the machine.

21. A machine in accordance with claim 20, further comprising a fourth process chamber connected to the central transport chamber, with the fourth process chamber being arranged between the second lock area and the central transport chamber in series with the second lock area and the central transport chamber.

22. A machine in accordance with claim 17, wherein one or more of the processing chambers, especially adjacent chambers, may be closed off from each other by a valve door.

23. A machine in accordance with claim 17, wherein the first process chamber is set up for the execution of a first treatment process, and the second process chamber and the third process chamber are set up for the execution of a second treatment process.

24. A machine in accordance with claim 17, wherein the machine is configured and arranged for the formation of thin film transistor metallization, with one of the layers in the layer sequence of the thin film transistor metallization being alternatively applied in the second process chamber or in the third process chamber.

25. A machine in accordance with claim 20, wherein the first lock area or the second lock area comprises a lock chamber and a transfer chamber.

26. A method of coating in a machine, the machine having at least a first process chamber, a second process chamber and a third process chamber; a central transport chamber to which at least the first, second, and third process chambers are connected; a first lock area for infeed or outfeed of the substrates into the machine or out of the machine; and wherein the first process chamber is arranged between the first lock area and the central transport chamber in series with the first lock area and the central transport chamber, and the second process chamber and the third process chamber being connected to the central transport chamber and accessible independently from each other, said method comprising the steps of:
a) infeeding a substrate into the machine;
b) transporting the substrate into the first process chamber;
c) executing a first treatment stage in the first process chamber;
d) transporting the substrate into the central transport chamber;
e) transporting the substrate alternatively into the second process chamber or into the third process chamber;
f) executing a second treatment stage;
g) returning the substrate into the central transport chamber; and
h) outfeeding the substrate from the machine.

27. A method in accordance with claim 26, further comprising:
transporting the substrate from the central transport chamber into a fourth coating chamber of the machine and executing a further treatment stage between steps g) and h).

28. A method in accordance with claim 26, further comprising:
transporting the substrate through an infeed chamber and a transfer chamber during the infeeding the substrate into the machine.

29. A method in accordance with claim 26, wherein the same process occurs in the second process chamber and in the third process chamber.

30. A method in accordance with claim 27, wherein one or more of the executing steps includes thin film transistor (TFT) metallization of at least three layers on to the substrate.

31. A method in accordance with claim 26, further comprising transporting a plurality of substrates through the machine and substantially vertically aligning the substrates during transport through the machine.

32. A method in accordance with claim 26, wherein the steps a)-h) are sequentially staggered in time, with at least a second substrate being repeated.
